(19) United States
(12) Patent Application Publication
(10) Pub. No.: US 2006/0083946 A1
(43) Pub. Date: Apr. 20, 2006

(54) Organic light emitting device

(75) Inventors: Su-Mi Lee, Suwon-si (KR); Joon-Young Park, Suwon-si (KR)

Correspondence Address: H.C. PARK & ASSOCIATES, PLC, 8500 LEESBURG PIKE, SUITE 7500, VIENNA, VA, 22182, US

(73) Assignee: Samsung SDI, Co., Ltd.

(21) Appl. No.: 11/228,264

(22) Filed: Sep. 19, 2005

(30) Foreign Application Priority Data
Oct. 15, 2004 (KR) 10-2004-0082570

(51) Int. Cl. H01L 51/50; H05B 33/12

(52) U.S. Cl. 428/690; 428/212; 428/213; 428/917; 313/504; 313/506

(57) ABSTRACT

An organic light emitting device is disclosed that may include a first electrode, a hole injecting layer, a hole transporting layer, an emitting layer, and a second electrode, wherein a ratio of thickness between the hole injecting layer and the hole transporting layer is in a range of about 1:1 to about 1:10. Since the relative thicknesses of the hole injecting layer and the hole transporting layer are controlled, leakage current in the organic light emitting device decreases. As a result, the electrical characteristics and the testability of the organic light emitting device may be improved.

### CROSS-REFERENCE TO RELATED PATENT APPLICATIONS

This application claims the benefit of Korean Patent Application No. 10-2004-0082570, filed on Oct. 15, 2004, in the Korean Intellectual Property Office, the disclosure of which is incorporated herein by reference in its entirety.

### BACKGROUND OF THE INVENTION

1. Field of the Invention

The present invention relates to an organic light emitting device, and more particularly, to an organic light emitting device with a hole injecting layer that reduces leakage current.

2. Description of Related Art

Organic light emitting devices are self emission devices that emit light by recombination of electrons and holes in a fluorescent or phosphorescent organic layer as current is supplied to the organic layer. Organic light emitting devices are lightweight, include simple components, and have a structure that can be manufactured through easy processes, superior image quality, and wide viewing angle. In addition, organic light emitting devices can create perfect moving pictures, can implement high color purity and have electrical properties, such as low power consumption, low driving voltage, etc., suitable for electronic devices.

Such organic light emitting devices include organic layers that may include a hole transporting layer, an emitting layer, an electron transporting layer, etc. The efficiency, driving voltage, chromaticity coordinates of an organic light emitting device may vary depending on a thickness of one or more organic layers. Thus the operating characteristics may vary depending on a thickness of a hole transporting layer, an emitting layer, an electron transporting layer, etc.

As a reverse bias voltage is applied to a hole transporting layer a fluorescent material in the hole transport layer may create a large off-state leakage current (Loff). When this occurs, black color cannot be normally expressed, and the testability of a resulting device deteriorates.

### SUMMARY OF THE INVENTION

The present invention provides an organic light emitting device in which a thickness ratio of a hole transporting layer to a hole injecting layer is adjusted to lower leakage current.

One embodiment of the invention may provide an organic light emitting device that includes a first electrode, a hole injecting layer, a hole transporting layer, an emitting layer, and a second electrode. A thickness ratio between the hole injecting layer and the hole transporting layer may be in a range of about 1:1 to about 1:10.

### BRIEF DESCRIPTION OF THE DRAWINGS

The above and other features and advantages of the present invention may become more apparent by describing in detail exemplary embodiments thereof with reference to the attached drawings.

FIG. 1 illustrates a structure of an organic light emitting device according to an embodiment of the present invention.

FIG. 2 illustrates a structure of an organic light emitting display according to an embodiment of the present invention that includes the organic light emitting device of FIG. 1.

FIG. 3 is a graph of current versus voltage for an organic light emitting device described in Example 1 and an organic light emitting device described in Comparative Example 1.

FIG. 4 is a graph illustrating leakage current characteristics of the organic light emitting devices described in Example 1 and Comparative Example 1.

### DETAILED DESCRIPTION OF THE INVENTION

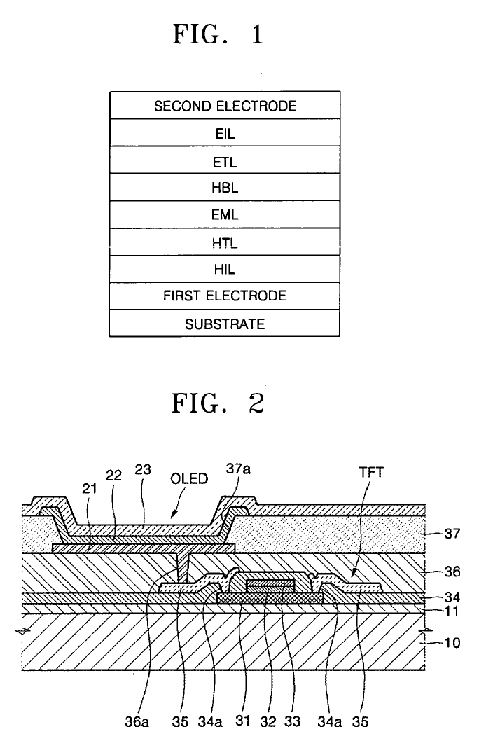

A method of manufacturing an organic light emitting device according to an embodiment of the present invention will be described with reference to FIG. 1.

Initially, an anode material is coated on a surface of a substrate to form an anode. Any suitable substrate commonly used in organic light emitting devices may be used. A glass substrate or transparent plastic substrate, which have superior surface flatness and waterproofness and are easy to handle, may be used. Indium tin oxide (ITO), zinc indium oxide (IZO), tin oxide (SnO₂), zinc oxide (ZnO), or etc., which are transparent and have superior conductivity, may be used as the anode material.

A material for forming a hole injecting layer is coated on the anode by vacuum thermal deposition or spin coating to form a hole injecting layer (HIL). The hole injecting layer may have a thickness of about 50 Å-800 Å, preferably, about 50 Å-150 Å. If the hole injecting layer is thinner than 50 Å, the lifespan and reliability of a resulting device may deteriorate. If the hole injecting layer is thicker than about 800 Å, the driving voltage may rise undesirably.

Examples of the material for forming the hole injecting layer that can be used include, but are not limited to, copper phthalocyanine, starburst amines, such as TCTA, m-MTDATA, etc.

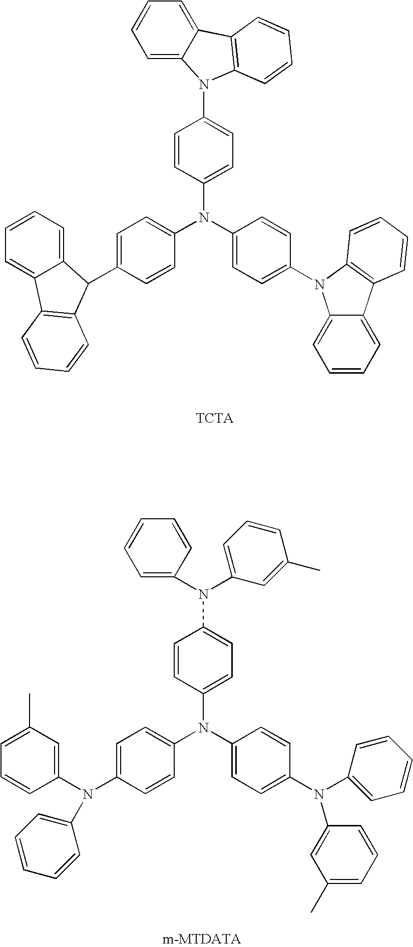

Hole injecting materials disclosed in Korean Patent Laid-open Publication No. 2004-0065667, and U.S. Pat. Nos. 5,837,166 and 6,074,734 may be used as the material for forming the hole injecting layer in the present invention.

A hole transporting material is coated on a surface of the hole injecting layer formed through the above-described process to form a hole transporting layer (HTL). Examples of the hole transporting material include, but are not limited to, N,N′-bis(3-methylphenyl)-N,N′-diphenyl-[1,1-biphenyl]-4,4′-diamine (TPD), N,N′-di(naphthalene-1-yl)-N, N′-diphenyl benzidine (NPB), etc. The hole transporting layer may be about 50 Å to about 1500 Å, preferably, about 200 Å to about 1200 Å thick. If the hole transporting layer is thinner than 50 Å, its ability to transport holes may deteriorate. If the hole transporting layer is thicker than 1500 Å, the driving voltage may rise undesirably.

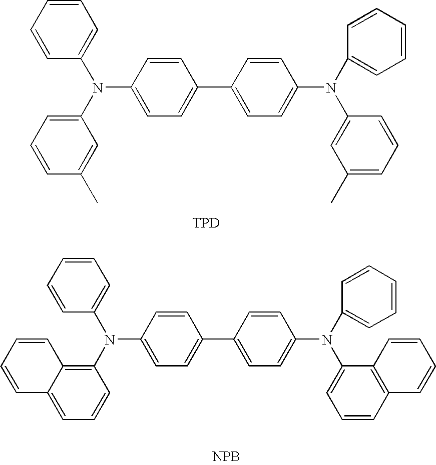

Next, an emitting layer (EML) is formed on the hole transporting layer. Any material can be used for the emitting layer without limitations. However, it is preferred that a phosphorescent material is used alone. Examples of phosphorescent materials that can be used in the present invention include Ir(ppy)₃ (ppy is an abbreviation for phenypyridine) (green), (4,6-F₂ ppy)₂Irpic (Chihaya Adachi etc. Appl. Phys. Lett., 79, 2082-2084, 2001), etc. The emitting layer may further contain a common host, such as CBP, in addition to a phosphorescent material used as a dopant. In this case, the amount of the dopant may be in a range of about 0.2 to about 3 parts by weight based on 100 parts by weight of the weight of the emitting layer (containing the dopant and the host). If the amount of the dopant is less than about 0.2 parts by weight, the light emitting efficiency deteriorates, and the driving voltage rises. Dopant more than 3 parts by weight may shorten the lifespan of a resulting light emitting device. A hole blocking layer (HBL) may be optionally formed on the emitting layer.

When forming a hole blocking layer, a material for forming the hole blocking layer is selectively coated on the emitting layer using vacuum deposition or spin coating to form the hole blocking layer. Any material that can transport electrons and have a higher ionization potential than light emitting compounds may be used to form the hole blocking layer without limitations. Representative examples of such materials for forming the hole blocking layer include Balq, BCP, TPBI, etc. The hole blocking layer may be about 30 Å to about 70 Å thick. If the hole blocking layer is thinner than about 30 Å, the holes cannot be blocked satisfactorily. If the hole blocking layer is thicker than about 70 Å, the driving voltage may undesirably rise.

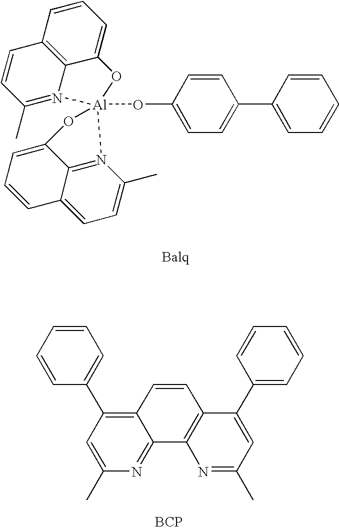

Next, an electron transporting layer (ETL) is formed on the hole blocking layer using vacuum deposition or spin coating.

The electron transporting layer may be formed using any material without limitations, preferably, Alq3. The electron transporting layer may be about 150 Å to about 600 Å thick. The electron transporting layer thinner than about 150 Å, may not transport electrons enough. If the electron transporting layer is thicker than 600 Å, the driving voltage may rise undesirably.

An electron injecting layer (EIL) may be selectively formed on the electron transporting layer. Suitable materials for the electron injecting layer may include LiF, NaCl, CsF, Li₂O, BaO, Liq, etc. The electron injecting layer may be about 5 Å to about 20 Å thick. If the electron injecting layer is thinner than about 5 Å, the electron injecting layer cannot effectively function. If the electron injecting layer is thicker than about 20 Å, the driving voltage may rise undesirably.

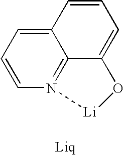

Next, a cathode, which is a second electrode, is formed on the electron injecting layer using vacuum thermal deposition, thereby resulting in a complete organic light emitting device. Metals that can be used to form the cathode may include Li, Mg, Al, Al—Li, Ca, Mg—In, Mg—Ag, etc.

An organic light emitting device according to the present invention may further include one or two intermediate layers if required. For example, the organic light emitting device may include an anode, a hole injecting layer, a hole transporting layer, an emitting layer, an electron transporting layer, an electron injecting layer, and a cathode.

The organic light emitting devices according to the present invention described above can be used in various displays, etc. An embodiment of an organic light emitting display including an organic light emitting device according to the present invention and an thin film transistor (TFT) will be described with reference to FIG. 2.

Referring to FIG. 2, a buffer layer 11 is formed on a substrate 10. The substrate 10 may be a glass substrate, a metal substrate, or an insulating polymeric substrate. In particular, for a flexible flat display, the substrate 10 may be a metal substrate such as a metal foil or an insulating polymeric substrate. Considering durability during crystallization processes, the metal substrate may be preferred. The metal substrate may contain at least one selected from the group consisting of iron, chromium, nickel, carbon, and manganese. In particular, the metal substrate may be formed of, for example, stainless steel, Ti, Mo, an Invar alloy, an Inconel alloy, a Kovar alloy, etc. The buffer layer 11 may be optionally formed on the substrate 10 to planarize the substrate 10. The buffer layer 11 may be composed of silicon oxide and/or silicon nitride.

A semiconductor active layer 31 for a TFT may be formed on the buffer layer 11. The TFT may be, but is not limited to, a driving TFT. Another switching TFT may be formed in a complicate circuit. The semiconductor active layer 31 may be either an inorganic; semiconductor layer having, for example, silicon or an organic semiconductor layer having, for example, pentacene

After the formation of the semiconductor active layer 31, a gate dielectric layer 32 and a gate electrode 33 may be sequentially formed on a channel region of the semiconductor active layer 31, and an insulating interlayer 34 covering the entire substrate 10 is formed.

A contact hole 34a is formed in the insulating interlayer 34, and a source/drain electrode 35 is formed on the insulating interlayer 34. The source/drain electrode 35 is electrically connected to the semiconductor active layer 31 through the contact hole 34a.

Various TFT structures, such as a bottom gate structure, not limited to the above-described structure of the TFT in FIG. 2, may also be used.

After the formation of the TFT, a planarizing layer 36 may be formed to cover the TFT. The planarizing layer 36 may be formed of a monolayer or a composite layer using an organic material and/or an inorganic material, like the above-described insulating layers.

After forming a via hole 36a in the planarizing layer 36, a first electrode layer 21 for an organic light emitting device (OLED) as described above may be formed on the planarizing layer 36. As a result, the first electrode layer 21 is connected with one of the source/drain electrodes 35 of the TFT.

Next, a pixel defining layer 37 may be formed to cover the planarizing layer 36 and the first electrode layer 21. An opening 37a may be formed in the pixel defining layer 37 to expose a predetermined portion of the first electrode layer 21. Like the planarizing layer 36 described above, the pixel defining layer 37 may be formed of a monolayer or a composite layer using an organic material and/or an inorganic material. An organic material is good for obtaining better surface flatness.

An organic emitting layer 22 and a second electrode layer 23 as described above may be sequentially formed on the exposed portion of the first electrode layer 21. Here, the organic emitting layer 22 includes the hole injecting layer, the hole transporting layer, the emitting layer, etc. described above.

The first electrode layer 21 functions as an anode, and the second electrode layer 23 functions as a cathode. The first electrode layer 21 may be patterned to a size corresponding to each pixel. The second electrode layer 23 may be formed to cover all of the pixels.

Regarding materials used to form the first electrode layer 21, the organic emitting layer 22, and the second electrode layer 23, methods used to form the same, and the thicknesses thereof, the descriptions of the light emitting device above can be referred to. After a complete OLED is obtained, an upper side of the OLED may be sealed to prevent the entry of external air.

While the organic light emitting display according to the present invention has been described with reference to the active matrix organic light emitting display in FIG. 2, this is for illustrative purposes only, and the organic light emitting display according to the present invention may be constructed to have various structures, for example, like a passive matrix organic light emitting display.

The present invention will be described in grater detail with reference to the following examples. The following examples are for illustrative purposes and are not intended to limit the scope of the invention.

### EXAMPLE 1

An indium tin oxide (ITO) glass substrate (available from Corning Co.) having a resistance of 15 Ω/cm² (1200 Å) was cut to a size of 50 mm×50 mm×0.7 mm and washed in isopropyl alcohol and pure water for 5 minutes each by ultrasonication and UV irradiation for 30 minutes and using ozone to be used as an anode.

Copper phthalocyanine (CuPc) was deposited on the substrate in a vacuum to form a hole injecting layer having a thickness of 100 Å. NPB was deposited on the hole injecting layer in a vacuum to form a hole transporting layer having a thickness of 800 Å. The thickness of the hole injecting layer and the thickness of the hole transporting layer were controlled to a ratio of 1:8.

Next, CBP and Irppy were deposited on the hole transporting layer to form an emitting layer having a thickness of about 400 Å. Alq3 was deposited on the emitting layer to form an electron transporting layer having a thickness of 250 Å.

LiF was deposited on the electron transporting layer to form an electron injecting layer having a thickness of 10 Å, and then Al was deposited on the electron injecting layer to form a cathode having a thickness of 1000 Å, thereby resulting in a complete organic light emitting device.

### EXAMPLE 2

An organic light emitting device was manufactured in the same manner as in Example 1, except that the thickness ratio between the hole injecting layer and the hole transporting layer was set 1:1.

### EXAMPLE 3

An organic light emitting device was manufactured in the same manner as in Example 1, except that the thickness ratio between the hole injecting layer and the hole transporting layer was set 1:10.

### COMPARATIVE EXAMPLE 1

An organic light emitting device was manufactured in the same manner as in Example 1, except that the thickness ratio between the hole injecting layer and the hole transporting layer was set 8:2.

### COMPARATIVE EXAMPLE 2

An organic light emitting device was manufactured in the same manner as in Example 1, except that the thickness ratio between the hole injecting layer and the hole transporting layer was set 1:0.5.

### COMPARATIVE EXAMPLE 3

An organic light emitting device was manufactured in the same manner as in Example 1, except that the thickness ratio between the hole injecting layer and the hole transporting layer was set 1:10.5.

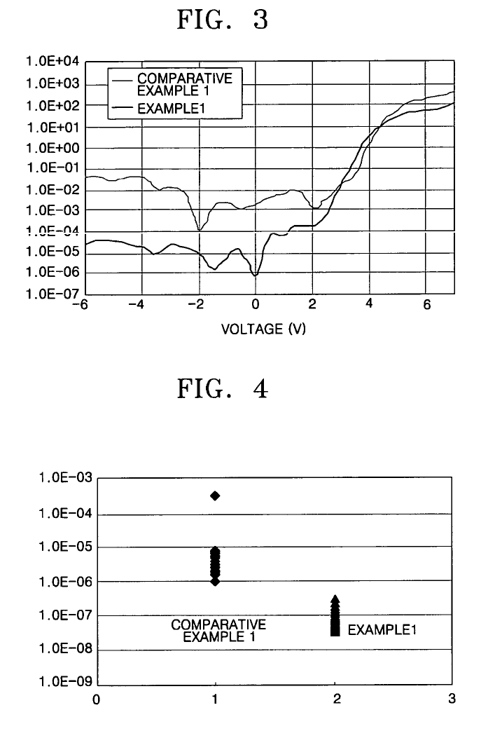

The current-voltage characteristic and the leakage current characteristic of each of the organic light emitting devices manufactured in Example 1 and Comparative Example 1 were measured. The results are shown in FIGS. 3 and 5.

Referring to FIG. 3, in the organic light emitting device according to Example 1, current leakage decreased in an Off-region. Referring to FIG. 4, the leakage current in the organic light emitting device according to Example 1 was smaller than the leakage current in the organic light emitting device according to Comparative Example 1.

As described above, in an organic light emitting device according to the present invention, the relative thicknesses between the hole injecting layer and the hole transporting layer are controlled to lower leakage current induced due to the hole injecting material. This improves the electrical characteristics and the testability of the organic light emitting device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light emitting device, comprising:
a first electrode;
a hole injecting layer formed on the first electrode;
a hole transporting layer formed on the hole injecting layer;
an emitting layer formed on the hole transporting layer; and
a second electrode formed over the emitting layer, wherein a ratio of thickness between the hole injecting layer and the hole transporting layer is in a range of about 1:1 to about 1:10.

2. The organic light emitting device of claim 1, wherein the ratio of thickness between the hole injecting layer and the hole transporting layer is in a range of about 1:4 to about 1:8.

3. The organic light emitting device of claim 1, wherein the hole injecting layer is about 50 Å to about 800 Å thick, and the hole transporting layer is about 50 Å to about 1500 Å thick.

4. The organic light emitting device of claim 1, wherein the hole injecting layer is made of a hole injecting material having a mobility of 1e⁻¹ cm²/Vs or greater, a LUMO (Lowest Unoccupied Molecular Orbital) energy level of about 2.7 eV or lower, a HOMO (Highest Occupied Molecular Orbital) energy level of about 5.0 eV or greater.

5. The organic light emitting device of claim 4, wherein the hole injecting material is copper phthalocyanine or m-MTDATA having the following formula:

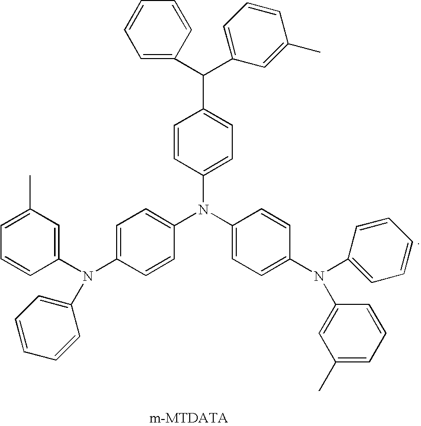

6. The organic light emitting device of claim 1; wherein the hole transporting layer is made of a hole transporting material having a mobility of 1e⁻⁴ cm²/Vs or greater, a LUMO energy level of about 3.3 eV or lower, a HOMO energy level of about 5.0 eV or greater.

7. The organic light emitting device of claim 5, wherein the hole transporting material is N,N′-bis(3-methylphenyl)-N,N′-diphenyl-[1,1-biphenyl]-4,4′-diamine (TPD) or N,N′-di(naphthalene-1-yl)-N, N′-diphenyl benzidine (NPB).

8. The organic light emitting device of claim 1, wherein the emitting layer contains a phosphorescent material.

9. An organic light emitting display comprising the organic light emitting device of claim 1.

10. The organic light emitting device of claim 1, further comprising a hole blocking layer formed on the emitting layer, wherein the hole blocking layer is about 30 Å to about 70 Å thick.

11. The organic light emitting device of claim 1, further comprising:
a hole blocking layer formed on the emitting layer;
an electron transporting layer formed on the hole blocking layer; and
an electron injecting layer formed on the electron transporting layer;
wherein the electron transporting layer is about 150 Å to about 600 Å thick; and
wherein the electron injecting layer is about 5 Å to about 20 Å thick.
